(19) United States
(12) Patent Application Publication
(10) Pub. No.: US 2025/0275433 A1
(43) Pub. Date: Aug. 28, 2025

(54) WINDOW AND DISPLAY DEVICE INCLUDING THE SAME

(71) Applicant: Samsung Display Co., Ltd., Yongin-si (KR)

(72) Inventors: SANGHOON KIM, Yongin-si (KR); HYUNJI LEE, Yongin-si (KR); BYUNGHOON KANG, Yongin-si (KR); JINGYU SIM, Yongin-si (KR); TAEHYEOG JUNG, Yongin-si (KR); SEONGJIN HWANG, Yongin-si (KR)

(73) Assignee: Samsung Display Co., Ltd., Yongin-si (KR)

(21) Appl. No.: 19/063,930

(22) Filed: Feb. 26, 2025

(30) Foreign Application Priority Data
Feb. 27, 2024 (KR) 10-2024-0028360

(51) Int. Cl. H10K 59/80; H10K 102/00

(52) U.S. Cl. CPC H10K 59/873; H10K 2102/311

(57) ABSTRACT

A window includes a display part and a pattern part. The display part has first sides extending in a first direction and second sides extending in a second direction transverse to the first direction. The pattern part surrounds the display part in a view in a third direction perpendicular to the first direction and the second direction. The pattern part includes a first pattern part extending along a side among the first sides and the second sides of the display part and includes a first pattern in the window, and a second pattern part adjacent to a transition region of the display part connecting a first side among the first sides to a second side among the second sides and includes a second pattern in the window. In the view, a shape of the first pattern is different from a shape of the second pattern.

### CROSS-REFERENCE TO RELATED APPLICATION(S)

This U.S. non-provisional patent application claims priority to and the benefits of Korean Patent Application No. 10-2024-0028360 under 35 U.S.C. § 119, filed in the Korean Patent Intellectual Property Office on Feb. 27, 2024, the entire contents of which are hereby incorporated by reference.

### BACKGROUND

### 1. Technical Field

The disclosure generally relates to a window and a display device including the same.

### 2. Description of the Related Art

In general, a display device may include a display panel including pixels to display an image, and a window disposed on the display panel to protect the display panel. The window may be made of, for instance, glass or transparent plastic materials. The window may protect the display panel from external scratches and impacts. The window may be attached to the display panel through an adhesive. An image generated by the display panel may pass through the window to be provided for users.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Some aspects provide a window capable of lessening an external impact and preventing (or at least mitigating the potential of) crack generation and/or propagation due to the external impact.

Some aspects provide a display device including a window capable of lessening an external impact and preventing (or at least mitigating the potential of) crack generation and/or propagation due to the external impact.

Additional aspects will be set forth in the detailed description, which follows, and in part, will be apparent from the disclosure, or may be learned by practice of the disclosed embodiments and/or the claimed subject matter.

According to an embodiment, a window includes a display part and a pattern part. The display part has first sides extending in a first direction and second sides extending in a second direction transverse to the first direction. The pattern part surrounds the display part in a view in a third direction perpendicular to the first direction and the second direction. The pattern part includes a first pattern part and a second pattern part. The first pattern part extends along a side among the first sides and the second sides of the display part. The first pattern part includes a first pattern in the window. The second pattern part is adjacent to a transition region of the display part. The transition region connects a first side among the first sides to a second side among the second sides. The second pattern part includes a second pattern in the window. In the view, a shape of the first pattern is different from a shape of the second pattern.

In an embodiment, in the view, an extending direction of the first pattern may be along the side of the display part, and an extending direction of the second pattern may change at least one time.

In an embodiment, the first pattern may include a first opening portion extending through the first pattern part in the third direction, and the second pattern may include a second opening portion extending through the second pattern part in the third direction.

In an embodiment, the first sides may be long sides of the display part, the second sides may be short sides of the display part, and the side may be one of the first sides. The first pattern may include a plurality of the first opening portion. At least two of the first opening portions may be spaced apart from one another in the first direction and at least two of the first opening portions may be spaced apart from one another in the second direction. The at least two first opening portions spaced apart from one another in the second direction may be offset from one another in the first direction.

In an embodiment, the first sides may be long sides of the display part, the second sides may be short sides of the display part, and the side may be one of the second sides. The first pattern may include a plurality of the first opening portion. At least two of the first opening portions may be spaced apart from one another in the first direction and at least two of the first opening portions may be spaced apart from one another in the second direction. The at least two first opening portions spaced apart from one another in the first direction may be offset from one another in the second direction.

In an embodiment, the first sides may be long sides of the display part, the second sides may be short sides of the display part, and the side may be one of the first sides. The first pattern may include a plurality of the first opening portion. The first opening portions may be spaced apart from one another in the second direction. Each of the first opening portions may have a corresponding wavy pattern shape in the view. A distance between waves of a first opening portion among the first opening portions that is closer to the display part than another first opening portion among the first opening portions may be different from a distance between waves of the another first opening portion.

In an embodiment, the first sides may be long sides of the display part, the second sides may be short sides of the display part, and the side may be one of the second sides. The first pattern may include a plurality of the first opening portion. The first opening portions may be spaced apart from one another in the first direction. Each of the first opening portions may have a corresponding wavy pattern shape in the view. A distance between waves of a first opening portion among the first opening portions that is closer to the display part than another first opening portion among the first opening portions may be different from a distance between waves of the another first opening portion.

In an embodiment, first parts of inner side surfaces of the first opening portion may extend in the third direction and may face one another in a direction perpendicular to the third direction.

In an embodiment, second parts of the inner side surfaces of the first opening portion may be oblique to the first parts and may connect the first parts to a first surface of the pattern part. The first opening portion may have a first end in the first surface. Third parts of the inner surfaces of the first opening portion may be oblique to the first parts and may connect the first parts to a second surface of the pattern part opposing the first surface of the pattern part in the third direction. The first opening portion may have a second end in the second surface.

In an embodiment, inner side surfaces of the first opening portion may bow convexly toward a central axis of the first opening portion.

In an embodiment, a transverse plane may divide inner side surfaces of the first opening portion into first surface parts adjacent to a first side of the transverse plane and second surface parts adjacent to a second side of the transverse plane. A shortest distance between the first surface parts may continuously increase in size from the transverse plane toward a first surface of the pattern part along the third direction. The first opening portion may terminate at the first surface.

In an embodiment, the first opening portion may be at least partially filled with a resin, and the second opening portion may be at least partially filled with the resin.

In an embodiment, the pattern part may include a first surface at which first ends of the first opening portion and the second opening portion terminate and a second surface at which second ends of the first opening portion and the second opening portion terminate. At least one of the first surface and the second surface may be coated with the resin. The resin may be a light-blocking resin.

In an embodiment, the pattern part may include a first surface at which first ends of the first opening portion and the second opening portion terminate and a second surface at which second ends of the first opening portion and the second opening portion terminate. At least one of the first surface and the second surface may be coated with the resin. The resin may be optically transparent.

In an embodiment, in a range of about 20° C. to about 22° C., the resin may have an elastic modulus in a range of about 1 MPa to about 5000 MPa.

In an embodiment, the first pattern may include a first groove in the first pattern part, and the second pattern may include a second groove in the second pattern part.

In an embodiment, the first groove may include a (1-1)-th groove and (1-2)-th groove. The (1-1)-th groove may extend from a first surface of the first pattern part toward a second surface of the first pattern part. The second surface may oppose the first surface. The (1-2)-th groove may extend from the second surface of the first pattern part toward the first surface of the first pattern part. Each of the (1-1)-th groove and the (1-2)-th groove may have a depth that is greater than half a thickness of the first pattern part.

In an embodiment, the first sides may be long sides of the display part and the second sides may be short sides of the display part. The side may be one of the long sides and a width of the first pattern part in the second direction may be in a range of about 50 μm to about 5000 μm, or the side may be one of the short sides and a width of the first pattern part in the first direction may be in a range of about 50 μm to about 5000 μm

According to an embodiment, a display device includes a display panel and a window disposed on the display panel. The window includes a display part and a pattern part. The display part has first sides extending in a first direction and second sides extending in a second direction transverse to the first direction. The pattern part surrounds the display part in a view in a third direction perpendicular to the first direction and the second direction. The pattern part includes a first pattern part and a second pattern part. The first pattern part extends along a side among the first sides and the second sides of the display part. The first pattern includes a plurality of first opening portions in the window. The second pattern part is adjacent to a transition region of the display part. The transition region connects a first side among the first sides to a second side among the second sides. The second pattern part includes a plurality of second opening portions in the window. In the view, shapes of each of the plurality of first opening portions are different from shapes of each of the plurality of second opening portions.

In an embodiment, at least some of the first opening portions and the second opening portions may be at least partially filled with resin.

According to an embodiment, a window includes a display part, a first pattern part, a second pattern part, and a third pattern part. The display part is disposed in a central portion of the window. The first pattern part extends in a first direction. The first pattern part is disposed between a first portion of a periphery of the window and the central portion in a view in a third direction perpendicular to the first direction. The second pattern part extends in a second direction transverse to the first direction and perpendicular to the third direction. The second pattern part is disposed between a second portion of the periphery and the central portion in the view. The third pattern part is disposed between a third portion of the periphery and the central portion in the view. The third portion of the periphery connects the first portion of the periphery to the second portion of the periphery. A first section of the third pattern part extends in the first direction. A second section of the third pattern part extends in the second direction. The first pattern part includes a first void pattern in the window. The third pattern part includes a second void pattern in the window. The second void pattern is different from the first void pattern.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is an assembled schematic perspective view of an electronic apparatus according to an embodiment.

FIG. 2 is an exploded schematic perspective view of the electronic apparatus illustrated in FIG. 1 according to an embodiment.

FIG. 3 is a schematic cross-sectional view of a display module illustrated in FIG. 2 according to an embodiment.

FIG. 4 is a schematic view illustrating an example of a cross-section of a display panel illustrated in FIG. 3 according to an embodiment.

FIG. 5 is a schematic plan view of a display module illustrated in FIG. 4 according to an embodiment.

FIG. 6 is a schematic plan view of a window illustrated in FIG. 2 according to an embodiment.

FIG. 7A is an enlarged schematic plan view of a first area AA1 illustrated in FIG. 6 according to an embodiment.

FIG. 7B is an enlarged schematic plan view of a second area AA2 illustrated in FIG. 6 according to an embodiment.

FIGS. 8A, 8B, 8C, and 8D are schematic views for describing a cross-section of a first pattern part illustrated in FIG. 6 according to some embodiments.

FIG. 9A is a schematic view for describing impact absorption of a pattern part against an external impact according to an embodiment.

FIG. 9B is a schematic view for describing crack-propagation prevention by first patterns according to an embodiment.

FIGS. 10A, 10B, and 10C are schematic views for describing a first pattern and a second pattern according to an embodiment.

FIGS. 11A, 11B, and 11C are schematic views for describing a first pattern and a second pattern according to an embodiment.

FIGS. 12A and 12B are schematic views for describing a window according to an embodiment.

FIGS. 13A and 13B are schematic views for describing a bezel part illustrated in FIG. 2 according to an embodiment.

FIG. 14 is a schematic plan view of a window according to an embodiment.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described in more detail with reference to the accompanying drawings.

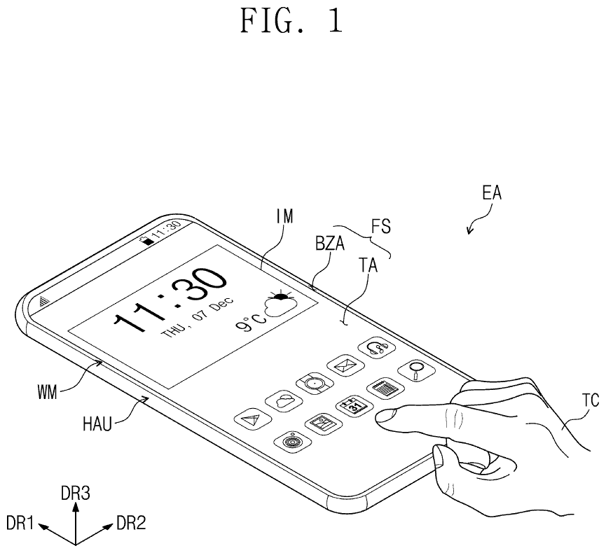

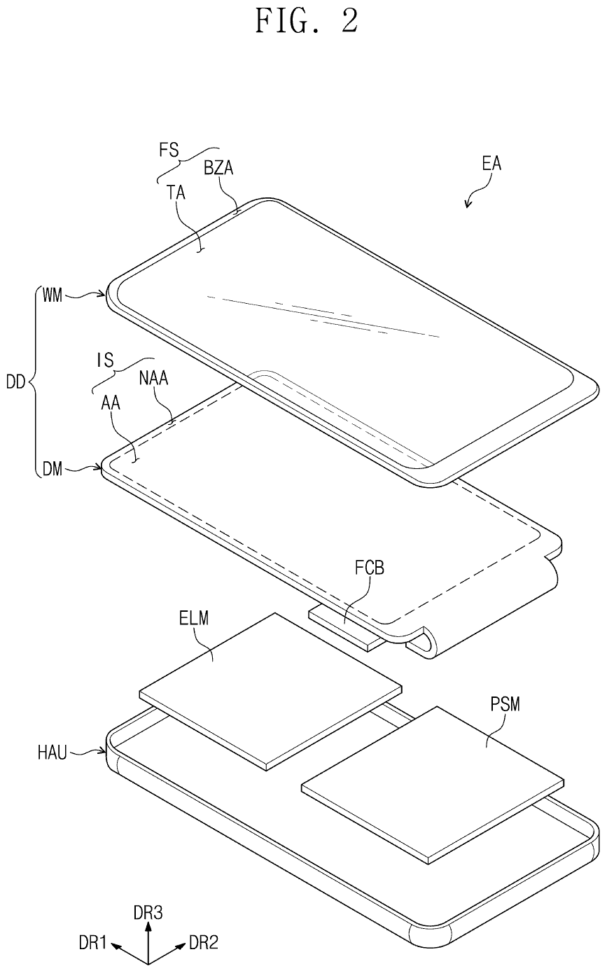

FIG. 1 is an assembled schematic perspective view of an electronic apparatus according to an embodiment. FIG. 2 is an exploded schematic perspective view of the electronic apparatus illustrated in FIG. 1 according to an embodiment.

Referring FIG. 1, an electronic apparatus EA may be an apparatus that is activated in response to an electrical signal, displays an image IM, and detects an external input TC. For example, the electronic apparatus EA may include an apparatus, such as at least one of a monitor, a mobile phone, a tablet computer, a navigation unit, and a game console. However, the foregoing embodiments of the electronic apparatus EA are examples, and are not limited to any one type. As shown in FIG. 1, a mobile phone is illustrated as an example of the electronic apparatus EA.

The electronic apparatus EA may have a generally rectangular shape having long sides extending in a first direction DR1 and having short sides extending in a second direction DR2 transverse to the first direction DR1 in a view in a third direction DR3 transverse to the first direction DR1 and the second direction DR3. Hereinafter, a view in the third direction DR3 may be referred to as a plan view. However, embodiments are not limited to this example. For instance, the electronic apparatus EA may have various shapes in a plan view, such as a circular shape, a polygonal shape, or any other suitable geometric shape.

In some embodiments, the third direction DR3 may be perpendicular to a plane defined by the first direction DR1 and the second direction DR2. A front surface (or top surface) and a rear surface (or bottom surface) of each of members (or elements), which constitute a portion of the electronic apparatus EA, may oppose each other in (or along) the third direction DR3, and a normal direction to each of the front surface and the rear surface may be substantially parallel to the third direction DR3. A spaced distance between the front surface and the rear surface, which is defined in the third direction DR3, may correspond to a thickness of the member.

The phrase “in a cross-section,” as used herein, may be defined as being a state in which a member is viewed in the first direction DR1 or the second direction DR2. It is noted, however, that directions indicated by the first to third directions DR1, DR2 and DR3 are relative concepts and may be changed to other directions.

The electronic apparatus EA may display the image IM through a display surface FS parallel (or substantially parallel) to each of the first direction DR1 and the second direction DR2. The image IM may include not only a dynamic image, but also a still image. FIG. 1A illustrates a clock and icons as an example of the image IM.

The display surface FS of the electronic apparatus EA may include only a flat surface, or may further include at least one curved surface bent (or otherwise extending) from at least one side of the flat surface. The display surface FS may not only correspond to a front surface of the electronic apparatus EA, but may also correspond to a front surface FS of a window WM. As such, call reference character “FS” is used to designate both the front surface FS of the electronic apparatus EA and the front surface FS of the window WM.

The electronic apparatus EA according to an embodiment may detect an external input TC applied from outside the electronic apparatus EA. The external input TC may include various types of external inputs, such as power, pressure, temperature, motion, sound, or light. As seen in FIG. 1, the external input TC is illustrated as a user's hand applied to the front surface of the electronic apparatus EA. However, the depicted external input TC is illustrative, and the external input TC may include a touch by a pen or an input, such as hovering or approaching event, which may be inputs adjacent (or relatively close) to the electronic apparatus EA.

The electronic apparatus EA may detect the user's input through the display surface FS (which may be defined as the front surface of the electronic apparatus), and may respond to a detected input signal. However, an area of the electronic apparatus EA, through which the external input TC may be detected, is not limited to the front surface of the electronic apparatus EA, and may be changed according to a design of the electronic apparatus EA. For example, the electronic apparatus EA may detect the user's input applied to a side surface or a rear surface of the electronic apparatus EA, or even multiple surfaces of the electronic apparatus EA.

Referring to FIGS. 1 and 2, the electronic apparatus EA may include a display device DD, an electronic module ELM, a power module PSM, and a housing HAU. The display device DD may include a display module DM and the window WM. The window WM and the housing HAU may constitute (or form) an outer appearance of the electronic apparatus EA. The window WM may extend from the housing HAU or may be coupled to (or otherwise supported by) the housing HAU.

The window WM may be disposed on the display module DM. The window WM may cover a front surface IS of the display module DM, and may protect the display module DM from external impacts and scratches. The window WM may extend from the display module DM or may be coupled to the display module DM through, for instance, an adhesive layer.

The window WM may include an optically transparent material, such as an optically transparent insulation material. For example, the window WM may include glass or synthetic resin as a base film. The window WM may have a single-layer structure or a multilayer structure. For example, the window WM having a multilayer structure may include synthetic resin films coupled to each other through one or more adhesives, or may include a glass film and a synthetic resin film coupled to each other through an adhesive. The window WM may further include at least one functional layer, such as at least one of an anti-fingerprint layer, a phase control layer, and a hard coating layer, which may be disposed on a base film, such as a transparent base film.

The front surface FS of the window WM may correspond to the front surface of the electronic apparatus EA. The front surface FS of the window WM may include a display part TA and a bezel part BZA. The display part TA may be an optically transparent area. The display part TA may transmit the image IM provided by the display module DM.

As seen in FIGS. 1 and 2, the display part TA is illustrated with a rectangular shape having long sides extending in the first direction DR1 and short sides extending in the second direction DR2 in a plan view. However, embodiments are not limited to the illustrated shape of the display part TA. For instance, the display part TA may have various shapes in a plan view.

The bezel part BZA may be an area having a relatively low light transmittance compared to the display part TA. The bezel part BZA may correspond to an area coated with a resin having a determined color. The bezel part BZA may prevent (or substantially prevent) transmission of light to prevent one (or a) component of the display module DM, which may overlap the bezel part BZA in the third direction DR3, from being visible from outside of the electronic apparatus EA. Hereinafter, unless stated otherwise, a first element overlapping a second element refers to the first element overlapping the second element in (or along) the third direction DR3.

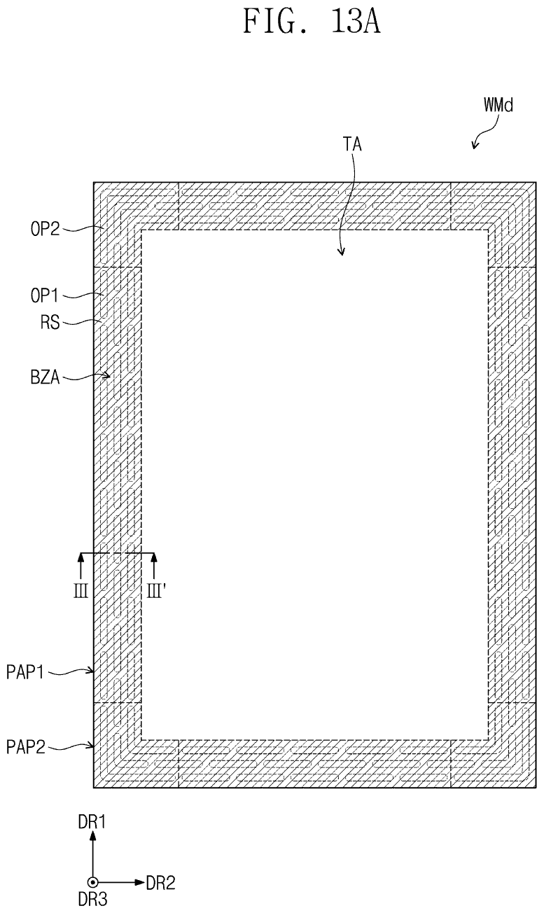

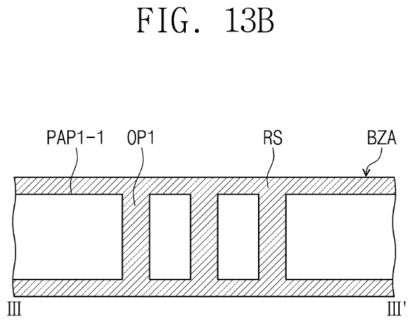

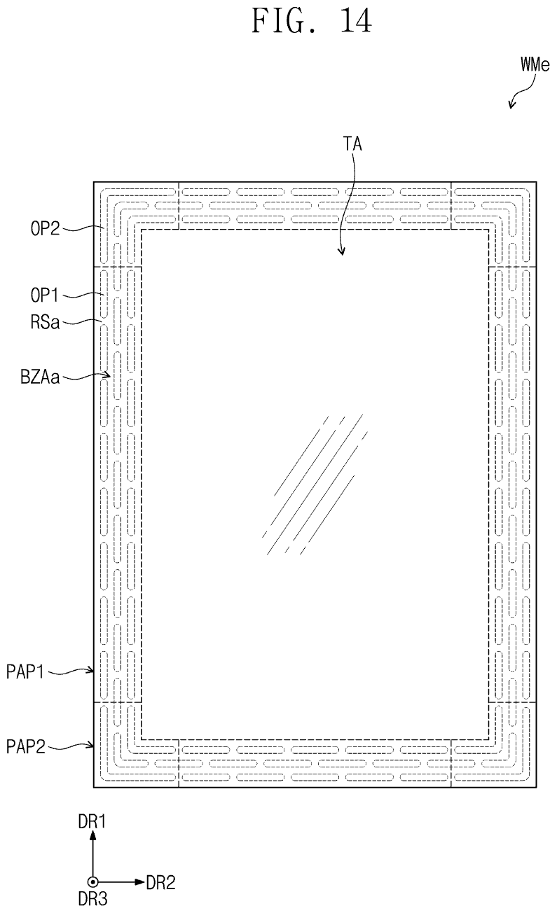

The bezel part BZA may be adjacent to the display part TA. A shape of the display part TA may be defined substantially (or at least partially bounded) by the bezel part BZA. For example, the bezel part BZA may be disposed outside the display part TA to surround (or circumscribe) the display part TA in a plan view. As used herein, the term “circumscribe” is not limited to a first feature forming a circle around a second feature, and as such, may include the first feature forming any suitable two-dimensional geometric figure around the second feature in a view in, for instance, the third direction DR3. To this end, a first feature “surrounding” or “circumscribing” a second feature may (unless otherwise specified) include an inner boundary of the first feature touching one or more points of an outer boundary of the second feature, or the inner boundary of the first feature may be spaced apart from the outer boundary of the second feature. Moreover, a first feature “surrounding” a second feature may include (unless otherwise specified) the first feature completely or partially surrounding the second feature in a view in, for instance the third direction DR3. The bezel part BZA may be disposed adjacent to an edge of the display part TA. However, the described adjacency of the bezel part BZA is illustrative. For instance, the bezel part BZA may be adjacent to only one side of the display part TA, or may be disposed on a side surface of the electronic apparatus EA. In some implementations, the bezel part BZA may not be disposed on the front surface FS of the electronic apparatus EA. As another example, the bezel part BZA may be omitted. The bezel part BZA will be described in more detail with reference to FIGS. 13A and 13B.

The display module DM may be disposed between the window WM and the housing HAU. The display module DM may display the image IM and detect the external input TC. The image IM may be displayed on (or through) the front surface IS of the display module DM. The front surface IS of the display module DM may include an active area AA and a peripheral area NAA.

The active area AA may be an area that is activated in response to an electrical signal. For example, the active area AA may be an area on (or through) which the image IM is displayed, and may also be an area through which the external input TC is detected. The active area AA may overlap at least a portion of the display part TA. The user may see the image IM through the display part TA, or may provide the external input TC relative to the display part TA. However, these examples are illustrative. For example, an area on which the image IM is displayed, and an area through which the external input TC is detected may be separated (or different) from each other in the active area AA, and are not limited to any one embodiment.

The peripheral area NAA may be adjacent to the active area AA. For example, the peripheral area NAA may surround the active area AA in a plan view. A driving circuit, a driving line, and/or the like for driving the active area AA may be disposed in the peripheral area NAA. The peripheral area NAA may overlap at least a portion of the bezel part BZA, and due to the bezel part BZA, components disposed in the peripheral area NAA may be prevented from being visible from outside the electronic apparatus EA.

The display module DM may include a display panel DP and an input sensing part ISP. The display panel DP may display the image IM, and the input sensing part ISP may detect the external input TC. This will be described in more detail later.

One (or a) portion of the display module DM may be bent (or flexed) around a bending axis extending in, for instance, the second direction DR2. For example, the portion of the display module DM may be bent about the bending axis and toward a rear surface of the display module DM, which opposes the active area AA (or the front surface FS) along the third direction DR3. A flexible circuit board FCB may be connected to the portion of the display module DM that is bent (or another portion of the display module DM that extends from the portion of the display module DM that is bent), and the flexible circuit board FCB may overlap the display module DM.

The flexible circuit board FCB may be electrically connected to the display module DM at one (or a) side of the display module DM. The flexible circuit board FCB may generate an electrical signal and provide the electrical signal to the display module DM, or may receive a signal (e.g., an electrical signal) generated by the display module DM to calculate (or determine) a result value including information about, for instance, a detected position or intensity of the external input TC.

The power module PSM may supply power for an operation of the electronic apparatus EA. For example, the power module PSM may include a battery module or other suitable power storage component.

The electronic module ELM may include various functional modules that operate or provide features to the electronic apparatus EA. For example, the electronic module ELM may include at least one of a control module, a wireless communication module, an image input module, a sound input module, a sound output module, a memory, an optical module, an external interface module, and the like. The electronic module ELM may include a main circuit board, and modules or blocks of the electronic module ELM may be mounted on the main circuit board or electrically connected to the main circuit board through a separate circuit board or other electrical connection, such as a ribbon cable.

The control module of the electronic module ELM may control the overall operation of the electronic apparatus EA. For example, the control module may activate or inactivate the display module DM in accordance with a user's input. The control module may include at least one processor, such as at least one microprocessor. The optical module of the electronic module ELM may include at least one of a camera module, a proximity sensor, a biometric sensor for recognizing a user's body part (e.g., fingerprint, iris, face, and/or the like), a lamp for outputting light, and/or the like.

The housing HAU may be coupled to the window WM to provide an inner space (or plenum) that at least partially accommodates the display module DM, the electronic module ELM, the power module PSM, and the flexible circuit board FCB. The housing HAU may include a material having relatively high rigidity. For example, the housing HAU may include at least one of glass, plastic, and metal, or may include multiple frames and/or plates made of at least one of glass, plastic, and metal. The housing HAU may at least partially absorb an impact applied from outside of the electronic apparatus EA and/or prevent (or mitigate) a foreign matter, moisture, etc., from being introduced from outside of the electronic apparatus EA, thereby protecting components of the electronic apparatus EA accommodated in (or by) the housing HAU.

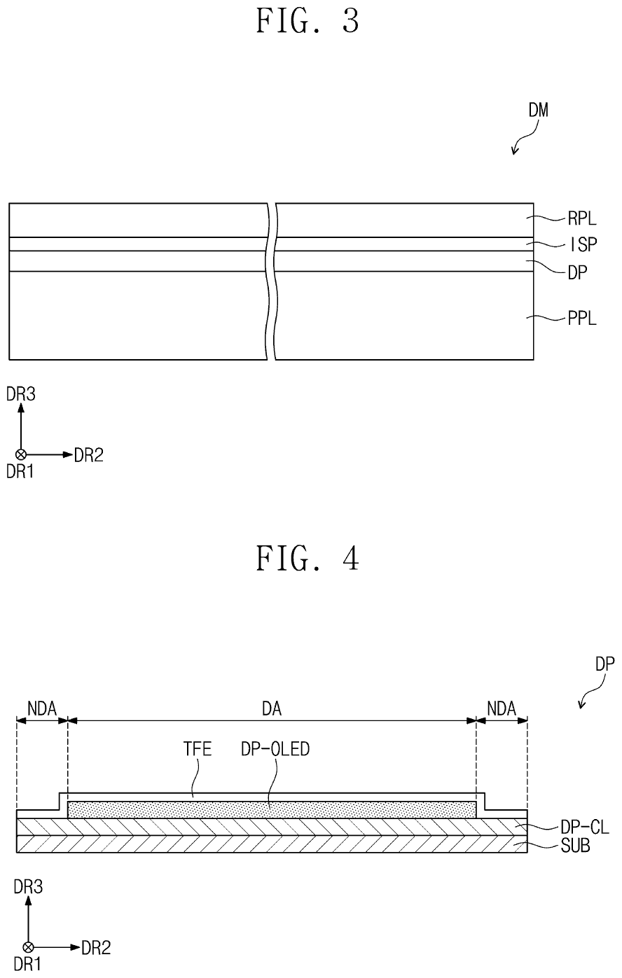

FIG. 3 is a schematic cross-sectional view of a display module illustrated in FIG. 2 according to an embodiment.

Referring to FIG. 3, the display module DM may include a display panel DP, an input sensing part ISP disposed on the display panel DP, an anti-reflection layer RPL disposed on the input sensing part ISP, and a panel protection layer PPL disposed below the display panel DP. The display panel DP may be a flexible display panel. For example, the display panel DP may include a flexible substrate and multiple elements disposed on the flexible substrate.

The display panel DP according to an embodiment may be an emissive display panel, but embodiments are not limited to emissive display panels. For example, the display panel DP may be an organic light emitting display panel or an inorganic light emitting display panel. A light emitting layer of the organic light emitting display panel may include an organic light emitting material. A light emitting layer of the inorganic light emitting display panel may include at least one of a quantum dot, a quantum rod, and the like. Hereinafter, the display panel DP is described as the organic light emitting display panel.

The input sensing part ISP may include multiple sensors (not illustrated) for detecting an external input by using, for instance, a capacitance method. The input sensing part ISP may be disposed on (e.g., directly on) the display panel DP during manufacture of the display module DM.

The anti-reflection layer RPL may be disposed on the input sensing part ISP. The anti-reflection layer RPL may be disposed directly on the input sensing part ISP during manufacture of the display module DM. The anti-reflection layer RPL may be a film that prevents (or at least mitigates) the reflection of external light. The anti-reflection layer RPL may reduce the reflectance of external light incident from above the display device DD toward the display panel DP.

As an example, the input sensing part ISP may be disposed directly on the display panel DP, and the anti-reflection layer RPL may be disposed directly on the input sensing part ISP. For instance, the input sensing part ISP and the anti-reflection layer RPL may form portions of the display panel DP. However, embodiments are not limited thereto. For example, the input sensing part ISP may be separately manufactured and attached (or coupled) to the display panel DP through, for instance, an adhesive layer, and the anti-reflection layer RPL may be separately manufactured and attached (or coupled) to the input sensing part ISP through, for instance, an adhesive layer.

The panel protection layer PPL may be disposed below the display panel DP. The panel protection layer PPL may protect a lower portion of the display panel DP. The panel protection layer PPL may include a flexible plastic material. For example, the panel protection layer PPL may include polyethylene terephthalate (PET).

FIG. 4 is a schematic view illustrating an example of a cross-section of a display panel illustrated in FIG. 3 according to an embodiment.

As an example, FIG. 4 is a schematic view illustrating a cross-section of the display panel DP viewed in the first direction DR1.

Referring to FIG. 4, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display area DA and a non-display area NDA outside (e.g., around) the display area DA. The substrate SUB may include glass, a flexible plastic material, such as polyimide (PI), or any combination of glass and a flexible plastic material. The display element layer DP-OLED may be disposed on the display area DA.

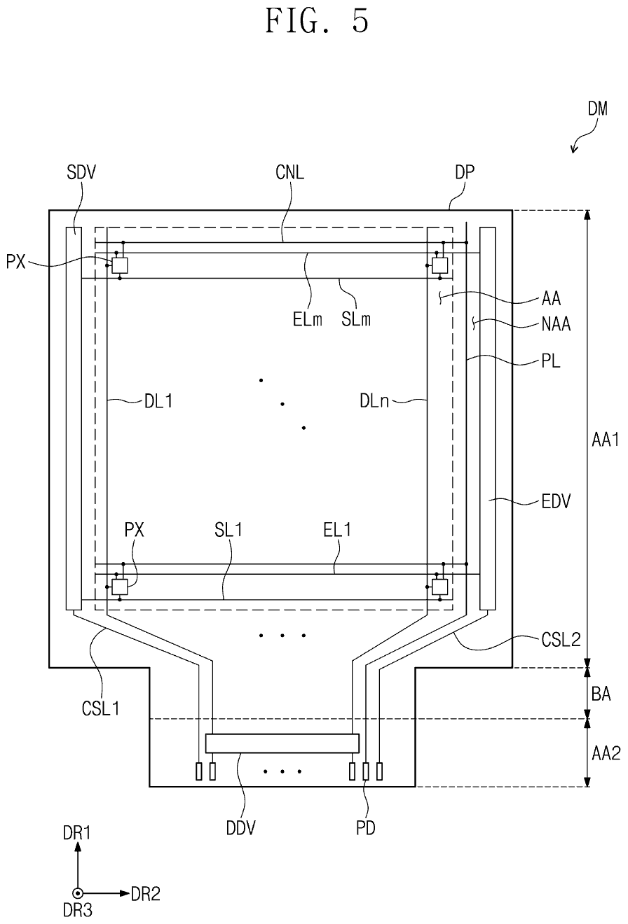

Multiple pixels PX (see FIG. 5) may be disposed in the circuit element layer DP-CL and the display element layer DP-OLED. Each of the pixels PX may include a transistor disposed in the circuit element layer DP-CL, and a light emitting element disposed in the display element layer DP-OLED and electrically connected to the transistor.

The thin-film encapsulation layer TFE may be disposed on the circuit element layer DP-CL to cover (or overlap) the display element layer DP-OLED. The thin-film encapsulation layer TFE may protect the pixels PX from, for instance, moisture, oxygen, and/or external foreign matter.

FIG. 5 is a schematic plan view of a display module illustrated in FIG. 4 according to an embodiment.

Referring to FIG. 5, the display module DM may include the display panel DP, a scan driver SDV, a data driver DDV, and an emission driver EDV.

The display panel DP may include a first area AA1, a second area AA2, and a bending area BA between the first area AA1 and the second area AA2. The bending area BA may extend in the second direction DR2, and each of the first area AA1, the bending area BA, and the second area AA2 may be arranged in (or along) the first direction DR1.

The first area AA1 may include a display area DA, and a non-display area NDA outside (e.g., around) the display area DA. The non-display area NDA may surround the display area DA. The display area DA may be an area that displays an image (e.g., image IM), and the non-display area NDA may be an area that does not display an image. The second area AA2 and the bending area BA may be areas that do not display an image. The display area DA may correspond to the active area AA (see FIG. 2) of the display module DM, and may overlap the display part TA (see FIG. 2) of the window WM (see FIG. 2).

The display panel DP may include pixels PX, scan lines SL1 to SLm, data lines DL1 to DLn, emission lines EL1 to ELm, first and second control lines CSL1 and CSL2, a power line PL, connection lines CNL, and pads PD. Here, “m” and “n” are each a natural number greater than one, and “m” may be equivalent to or different from “n.” The pixels PX may be disposed in the display area DA, and connected to the scan lines SL1 to SLm, the data lines DL1 to DLn, and the emission lines EL1 to ELm.

The scan driver SDV and the emission driver EDV may be disposed in the non-display area NDA. Each of the scan driver SDV and the emission driver EDV may be disposed in the non-display area NDA adjacent to opposing sides of the first area AA1. For instance, the scan driver SDV may be disposed in a portion of the non-display area NDA adjacent to a first side of the first area AA1 and the emission driver EDV may be disposed in another portion of the non-display area NDA adjacent to a second side of the first area AA1 that opposes the first side of the first area AA1 in the second direction DR2. The data driver DDV may be disposed in the second area AA2. The data driver DDV may be an integrated circuit chip and may be mounted on (or coupled to) the second area AA2.

The scan lines SL1 to SLm may extend in the second direction DR2 and may be electrically connected to the scan driver SDV. The data lines DL1 to DLn may extend in the first direction DR1 and may be electrically connected to the data driver DDV via the bending area BA. The emission lines EL1 to ELm may extend in the second direction DR2 and may be electrically connected to the emission driver EDV.

The power line PL may extend in the first direction DR1 and may be disposed in the non-display area NDA. The power line PL may be disposed between the display area DA and the emission driver EDV in a plan view. However, embodiments are not limited to this structure. For instance, the power line PL may be disposed between the display area DA and the scan driver SDV in a plan view.

The power line PL may extend to the second area AA2 via the bending area BA. The power line PL may extend toward a lower end of the second area AA2 in a plan view. The power line PL may receive a driving voltage.

The connection lines CNL may extend in the second direction DR2 and may be arranged (e.g., spaced part from one another) in (or along) the first direction DR1. The connection lines CNL may be electrically connected to the power line PL and the pixels PX. The driving voltage may be applied to the pixels PX through the power line PL and the connection lines CNL, which may be electrically connected to each other.

A first control line CSL1 may be electrically connected to the scan driver SDV and may extend toward the lower end of the second area AA2 via the bending area BA. A second control line CSL2 may be electrically connected to the emission driver EDV and may extend toward the lower end of the second area AA2 via the bending area BA. The data driver DDV may be disposed between the first control line CSL1 and the second control line CSL2 in a plan view.

The pads PD may be adjacent to the lower end of the second area AA2 in a plan view. The data driver DDV, the power line PL, the first control line CSL1, and the second control line CSL2 may be electrically connected to the pads PD.

The data lines DL1 to DLn may be electrically connected to corresponding pads PD among the pads PD through the data driver DDV. For example, the data lines DL1 to DLn may be electrically connected to the data driver DDV, and the data driver DDV may be electrically connected to those pads PD among the pads PD that are electrically connected to the data lines DL1 to DLn, respectively.

Although not illustrated, a printed circuit board may be electrically connected to the pads PD, and a timing controller and a voltage generator may be disposed on the printed circuit board. In some implementations, the printed circuit board may be the flexible circuit board FCB (see FIG. 2) or may be electrically connected to the flexible circuit board FCB. The timing controller may be an integrated circuit chip mounted on the printed circuit board. The timing controller and the voltage generator may be electrically connected to the pads PD through the printed circuit board.

The timing controller may control an operation of each of the scan driver SDV, the data driver DDV, and the emission driver EDV. The timing controller may generate a scan control signal, a data control signal, and an emission control signal in response to control signals received from outside the electronic apparatus EA. The voltage generator may generate the driving voltage.

The scan control signal may be provided to the scan driver SDV through the first control line CSL1. An emission control signal may be provided to the emission driver EDV through the second control line CSL2. The data control signal may be provided to the data driver DDV. The timing controller may receive image signals from outside the electronic apparatus EA, and may convert a data format of the image signals to match (or be compatible with) an interface specification of the data driver DDV so as to provide signals to the data driver DDV for driving the pixels PX.

The scan driver SDV may generate scan signals in response to the scan control signal. The scan signals may be applied to the pixels PX through the scan lines SL1 to SLm. The scan signals may be sequentially applied to the pixels PX.

The data driver DDV may generate data voltages corresponding to the image signals in response to the data control signal. The data voltages may be applied to the pixels PX through the data lines DL1 to DLn. The emission driver EDV may generate emission signals in response to the emission control signal. The emission signals may be applied to the pixels PX through the emission lines EL1 to ELm.

The pixels PX may receive the data voltages in response to the scan signals. The pixels PX may display an image (e.g., image IM) by emitting light with brightness corresponding to the data voltages in response to the emission signals. An emission time of the pixels PX may be controlled by the emission signals.

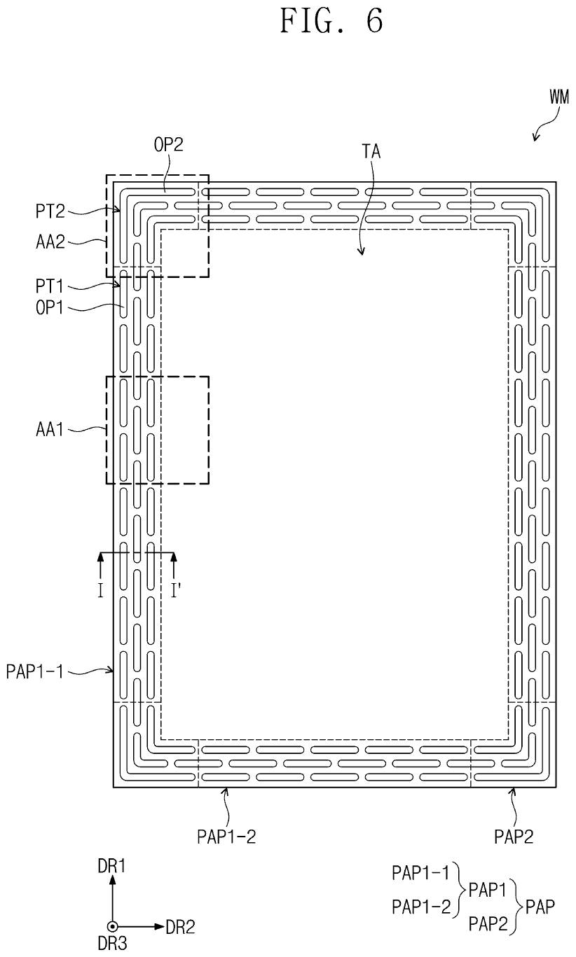

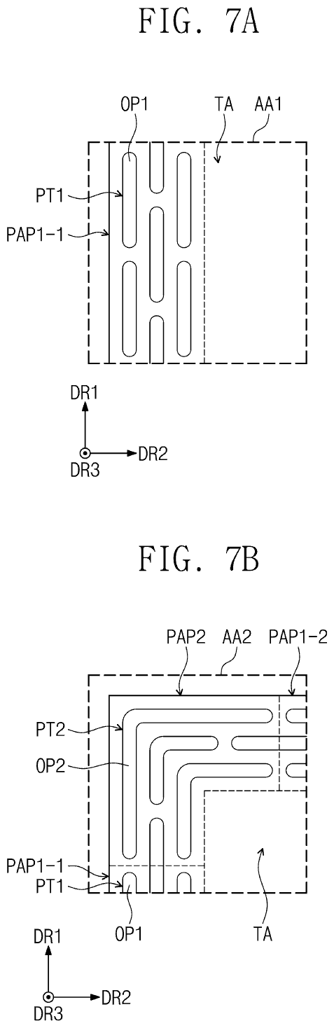

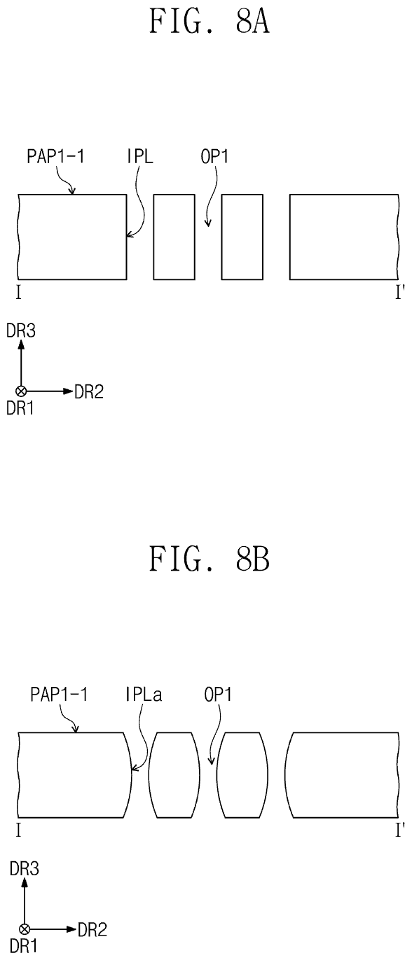

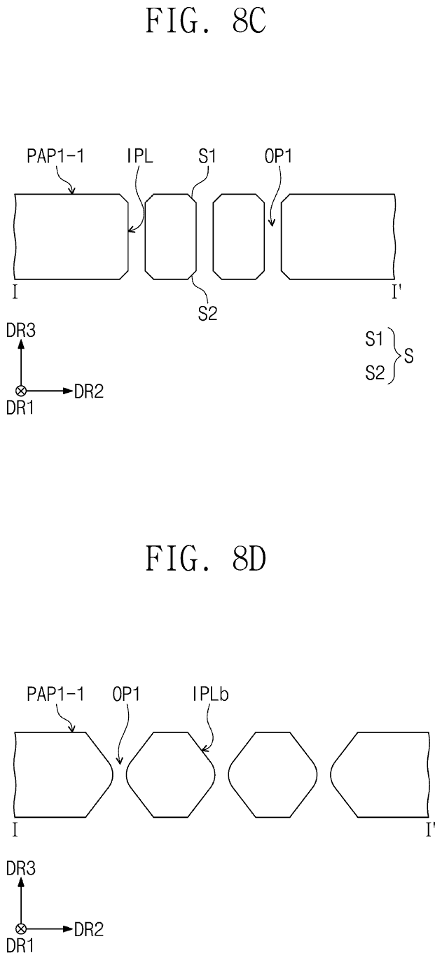

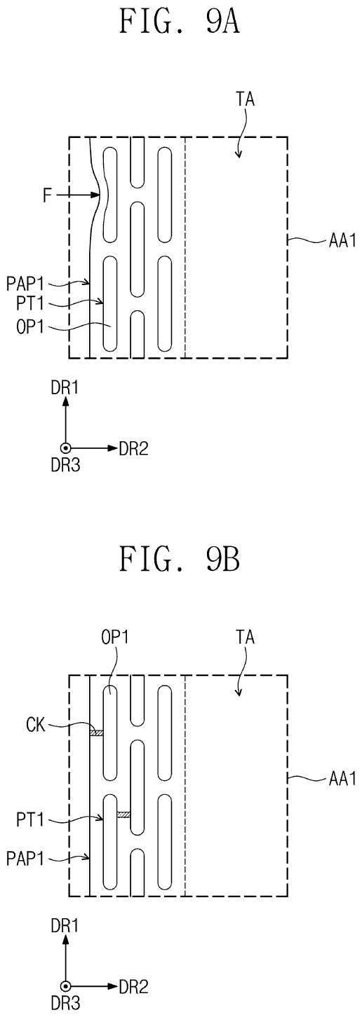

FIG. 6 is a schematic plan view of a window illustrated in FIG. 2 according to an embodiment. FIG. 7A is an enlarged schematic plan view of a first area AA1 illustrated in FIG. 6 according to an embodiment. FIG. 7B is an enlarged schematic plan view of a second area AA2 illustrated in FIG. 6 according to an embodiment. FIGS. 8A to 8D are schematic views for describing a cross-section of a first pattern part illustrated in FIG. 6 according to some embodiments. FIG. 9A is a schematic view for describing impact absorption of a pattern part against an external impact according to an embodiment. FIG. 9B is a schematic view for describing crack-propagation prevention by first patterns according to an embodiment.

As examples, FIGS. 8A to 8D illustrate schematic cross-sections corresponding to sectional line I-I′ illustrated in FIG. 6.

As an example, a cross-section of a (1-1)-th pattern part PAP1-1 will be described with reference to FIGS. 8A to 8D, but a (1-2)-th pattern part PAP1-2 and/or a second pattern part PAP2 may have substantially a same cross-section as the (1-1)-th pattern part PAP1-1.

FIGS. 8A to 8D illustrate example structures including multiple first pattern parts PAP1, but the structures may include a single pattern part PAP1.

As an example, FIGS. 9A and 9B are schematic plan views of an area corresponding to the first area AA1 illustrated in FIG. 6.

A display part TA illustrated in FIG. 6 is the same as the display part TA illustrated in FIG. 2, and thus, will not be described or will be briefly described.

Referring to FIGS. 6 and 7A, the display part TA may have a rectangular shape having long sides extending in the first direction DR1 and short sides extending in the second direction DR2 in a plan view.

The window WM may further include a pattern part PAP. The pattern part PAP may be adjacent to at least one of the long sides of the display part TA and/or at least one of the short sides of the display part TA. As an example, the pattern part PAP shown in FIG. 6 may be adjacent to the long sides and the short sides of the display part TA to surround the display part TA in a plan view. Hereinafter, an embodiment in which the pattern part PAP is adjacent to the long sides and the short sides of the display part TA will be described.

The pattern part PAP may include first pattern parts PAP1 and second pattern parts PAP2. A first some of the first pattern parts PAP1 may be adjacent to (or extend along) the long sides of the display part TA in the first direction DR1. A second some of the first pattern parts PAP1 may be adjacent to (or extend along) the short sides of the display part TA in the second direction DR2. Hereinafter, the first pattern parts PAP1 adjacent to the long sides of the display part TA will be referred to as (1-1)-th pattern parts PAP1-1, and the first pattern parts PAP1 adjacent to the short sides of the display part TA will be referred to as (1-2)-th pattern parts PAP1-2.

The (1-1)-th pattern parts PAP1-1 may extend along the long sides of the display part TA in the first direction DR1, and may be spaced apart from each other in the second direction DR2. The (1-2)-th pattern parts PAP1-2 may extend along the short sides of the display part TA in the second direction DR2, and may be spaced apart from each other in the first direction DR1.

A width of each of the (1-1)-th pattern parts PAP1-1 in the second direction DR2 may be in a range of about 50 μm to about 5000 μm. A width of each of the (1-2)-th pattern parts PAP1-2 in the first direction DR1 may be in a range of about 50 μm to about 5000 μm.

The first pattern parts PAP1 may include multiple first patterns PT1. As an example, the first patterns PT1 may be multiple first opening portions OP1 in the first pattern parts PAP1. The first opening portions OP1 may be arranged according to a determined rule or pattern. The first opening portions OP1 may be arranged in a lattice shape or formation. In a plan view, the first opening portions OP1 may each have a stadium shape or other geometric shape.

The first opening portions OP1 in the (1-1)-th pattern parts PAP1-1 may extend further in the first direction DR1 than in the second direction DR2. The first opening portions OP1 in the (1-1)-th pattern parts PAP1-1 may be arranged (or spaced apart from one another) in the first direction DR1 and the second direction DR2. The first opening portions OP1 adjacent to each other in the second direction DR2 may be misaligned with each other. For instance, the first opening portions OP1 adjacent to each other in the second direction DR2 may be arranged in a staggered pattern.

In some implementations, the first opening portions OP1 in a k-th row in order of increasing distance from the display part TA in the second direction DR2 may be misaligned (e.g., offset in the first direction DR1) with the first opening portions OP1 in a (k+1)-th row. As an example, the first opening portions OP1 may be arranged in three rows, but the number of the rows is not limited to three. A row of the first opening portions OP1 corresponds to those first opening portions OP1 aligned (or substantially aligned) with one another along the first direction DR1, and “k” may be a natural number of one or more.

The first opening portions OP1 in the (1-2)-th pattern parts PAP1-2 may extend further in the second direction DR2 than in the first direction DR1. The first opening portions OP1 in the (1-2)-th pattern parts PAP1-2 may be arranged (or spaced apart from one another) in the first direction DR1 and the second direction DR2. The first opening portions OP1 adjacent to each other in the first direction DR1 may be misaligned with each other. For instance, the first opening portions OP1 adjacent to each other in the first direction DR1 may be arranged in a staggered pattern.

In some implementations, the first opening portions OP1 in a h-th column in order of increasing distance from the display part TA in the first direction DR1 may be misaligned (e.g., offset in the second direction DR2) with the first opening portions OP1 defined in a (h+1)-th column. As an example, the first opening portions OP1 may be arranged in three columns, but the number of the columns is not limited to three. A column of the first opening portions OP1 corresponds to those first opening portions OP1 aligned (or substantially aligned) with one another along the second direction DR2, and “h” may be natural number of one or more.

Referring to FIG. 8A, in a view in the first direction DR1, respective inner side surfaces IPL of the (1-1)-th pattern parts PAP1-1 that define the first opening portions OP1 may each have a straight-line shape extending in the third direction DR3. Hereinafter, the inner side surfaces IPL of the (1-1)-th pattern parts PAP1-1 may be surfaces facing each other so as to define the first opening portions OP1.

Referring to FIG. 8B, in a view in the first direction DR1, inner side surfaces IPLa of the (1-1)-th pattern parts PAP1-1 may have shapes bowing toward central regions of the first opening portions OP1, respectively. For instance, the inner side surfaces IPLa may have a convex curvature bowing toward the central regions of the first opening portions OP1, respectively.

Referring to FIG. 8C, in a view in the first direction DR1, each of the (1-1)-th pattern parts PAP1-1 may further include inclined surfaces S, which may extend from and may be oblique to the inner side surfaces IPL extending in the third direction D3. The inclined surfaces S may include first inclined surfaces S1 and second inclined surfaces S2.

The first inclined surfaces S1 may connect first (e.g., top) surfaces of the (1-1)-th pattern parts PAP1-1 to the inner side surfaces IPL of the (1-1)-th pattern parts PAP1-1, respectively. The second inclined surfaces S2 may connect second (e.g., bottom) surfaces of the (1-1)-th pattern parts PAP1-1 to the inner side surfaces IPL of the (1-1)-th pattern parts PAP1-1, respectively.

Referring to FIG. 8D, in a view in the first direction DR1, inner side surfaces IPLb of the (1-1)-th pattern parts PAP1-1 may each have a tapered shape having a dimension in the second direction DR2 that varies along the third direction DR3. A distance (e.g., a shortest distance) between the inner side surfaces IPLb facing each other in the second direction DR2 may gradually increase from a point of the (1-1)-th pattern part PAP1-1, which may correspond to about half (½) a thickness of the (1-1)-th pattern part PAP1-1, toward the first (e.g., top) surface or the second (e.g., bottom) surface of the (1-1)-th pattern part PAP1-1. As used herein, a “gradually” changing parameter (such as a gradually changing distance) shall be understood to mean that the change in the parameter continuously varies between at least two reference points as opposed to varying with one or more distinct, abrupt transitions. For instance, a “gradual” change in a parameter may be a continuous linear change and/or a continuous non-linear change in the parameter between at least two reference points. In some implementations, a transverse plane parallel (or substantially parallel) to a DR1-DR2 plane may extend through (or include) the point of the (1-1)-th pattern part PAP1-1 and may divide the inner side surfaces IPLb into first parts adjacent to a first side of the transverse plane and second parts adjacent to a second side of the transverse plane.

The first opening portions OP1 defined (or at least partially bounded) by the inner side surfaces IPLb may be symmetrical in the third direction DR3 about an axis of symmetry that passes through the point corresponding to, for instance, about one half (½) the thickness of the (1-1)-th pattern part PAP1-1 and extends in the second direction DR2.

Referring to FIGS. 6 and 7B, the second pattern parts PAP2 may be adjacent to transition regions connecting the long sides of the display part TA to the second sides of the display part TA. The transition regions may be corners of the display part TA, respectively. In some implementations, the transition regions may include a first part extending in (or along) the first direction DR1, a second part extending in (or along) the second direction DR2, and an extending portion (e.g., an arcuate extending portion) connecting the first part to the second part. Hereinafter, it will be assumed that the transition regions are corners of the display part TA. As an example, the second pattern parts PAP2 may be adjacent to four corners of the display part TA, respectively, in a plan view. Each of the second pattern parts PAP2 may extend in (or along) the first direction DR1 and the second direction DR2.

The (1-1)-th pattern parts PAP1-1 may be disposed between the second pattern parts PAP2 arranged in the first direction DR1 in a plan view. The (1-2)-th pattern parts PAP1-2 may be disposed between the second pattern parts PAP2 arranged in the second direction DR2 in a plan view.

The second pattern parts PAP2 may include second patterns PT2. As an example, the second patterns PT2 may be multiple second opening portions OP2 in the second pattern parts PAP2.

Shapes of the second opening portions OP2 may be different from shapes of the first opening portions OP1 in a plan view. For instance, the second opening portions OP2 may have shapes corresponding to the corners of the display part TA in a plan view. Each of the second opening portions OP2 may include a first part extending in (or along) the first direction DR1 and a second part extending from the first part in (or along) the second direction DR2. An extending direction of the second opening portions OP2 may be changed at least one time.

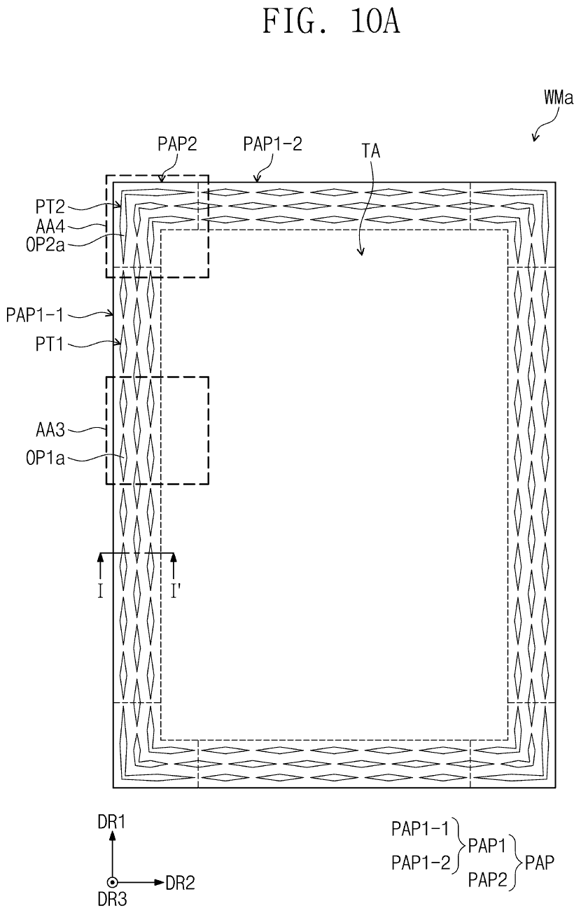

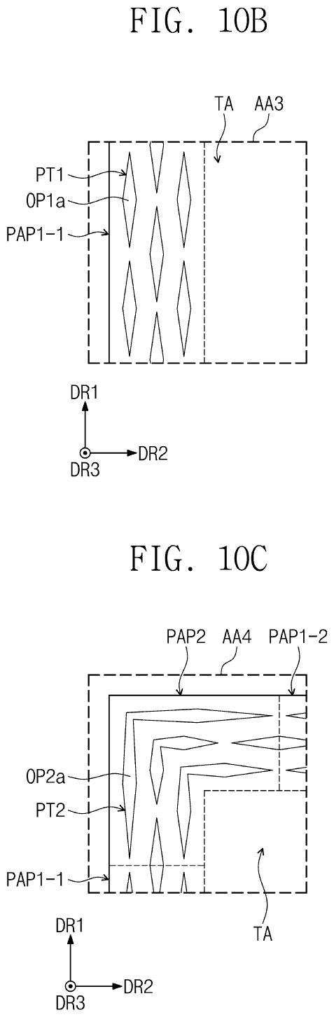

As an example, the second opening portions OP2 may each have a gnomon shape (e.g., a rectangular gnomon shape, such as an “L” or a rotated “L” shape) in a plan view, but the shapes of the second opening portions OP2 are not limited to these example shapes. The shapes of the second opening portions OP2 will be described in more detail with reference to FIGS. 10A, 11A, and 12A.

Although not illustrated, inner side surfaces of the second pattern parts PAP2, which define (or at least partially bound) the second opening portions OP2, may have substantially a same shapes as the inner side surfaces IPL, IPLa, and IPLb of the first pattern parts PAP1 described with reference to FIGS. 8A to 8D.

Referring to FIGS. 1, 6, and 9A, due to, for instance, a fall (or drop) of the electronic apparatus EA, or the like, an external impact F may be applied to the electronic apparatus EA. The external impact F may be applied to the window WM or a force of the external impact F may be transferred to the window WM. In a case in which the window WM does not include the pattern part PAP, the external impact F may be applied directly to the display part TA. The display part TA to which the external impact F is applied or transferred may be damaged, and a quality of the electronic apparatus EA that displays the image IM for a user may be reduced or non-existent.

However, according to some embodiments, the pattern part PAP may surround the display part TA. The pattern part PAP may include the first patterns PT1 and the second patterns PT2. As an example, the first patterns PT1 may be the first opening portions OP1, and the second patterns PT2 may be the second opening portions OP2. At least because the first opening portions OP1 are included, the first pattern parts PAP1 may be bent (or deformed) toward the first opening portions OP1. As the first pattern parts PAP1 are bent, a force of the external impact F applied to the window WM may be absorbed. Absorption of the force of the external impact F may prevent (or mitigate the likelihood of) the display part TA being damaged, and thereby, may improve the quality and/or reliability of the electronic apparatus EA.

Although not illustrated, in a case that the external impact F is applied or transferred to the second pattern parts PAP2, the second pattern parts PAP2 may be bent (or deformed) toward the second opening portions OP2. As the second pattern parts PT2 are bent, a force of the external impact F applied to the window WM may be absorbed by at least one of the second pattern parts PAP2. Absorption of the force of the external impact F may prevent (or at least mitigate the likelihood of) the display part TA being damaged, and thereby, may improve the quality and/or reliability of the electronic apparatus EA.

Referring to FIGS. 1, 6, and 9B, in a case in which the external impact F (see FIG. 9A) is applied to the window WM, a crack CK may be generated in the first pattern parts PAP1. At least because first opening portions OP1 are formed in the first pattern parts PAP1, propagation of the crack CK may be prevented or at least mitigated. In some implementations, the crack CK may not be able to propagate to the display part TA. In some instances, absorption of a force of the external impact F may cause, at least in part, one or more cracks CK to be formed in a first pattern part PAP1 at different distances from an edge of the electronic apparatus EA in, for instance, the second direction DR2. However, even in a case in which multiple cracks CK are formed in the first pattern part PAP1 (such as shown in FIG. 9B), not only may the multiple cracks CK be prevented (or mitigated) from reaching the display part TA, but the multiple cracks CK may also be prevented (or mitigated) from combining with one another due, at least in part, to the presence of the first opening portions OP1. Thus, a quality and/or reliability of the electronic apparatus EA that displays the image IM for a user may be improved.

Although not illustrated, in a case in which the crack CK is generated in at least one of the second pattern parts PAP2, due, at least in part, to the presence of the second opening portions OP2, propagation of the crack CK may be prevented or at least mitigated.

FIGS. 10A to 10C are schematic views for describing a first pattern and a second pattern according to an embodiment.

As an example, FIG. 10A is a schematic plan view of a window WMa, FIG. 10B is an enlarged schematic plan view of a third area AA3 illustrated in FIG. 10A, and FIG. 10C is an enlarged schematic plan view of a fourth area AA4 illustrated in FIG. 10A according to an embodiment.

A display part TA of the window WMa illustrated in FIGS. 10A to 10C is equivalent to the display part TA described in conjunction with FIG. 6, and thus, will not be described or will be briefly described.

For convenience of explanation, the window WMa in FIGS. 10A to 10C will be described mainly in terms of differences with the window WM described in association with FIG. 6.

Referring to FIGS. 10A and 10B, first patterns PT1 may be multiple first opening portions OP1a in a first pattern part PAP1. The first opening portions OP1a may each have a shape corresponding to a rhombus in a plan view. The first opening portions OP1a may be arranged according to a determined rule or pattern. The first opening portions OP1a may be arranged in a lattice shape or pattern.

The first opening portions OP1a in (1-1)-th pattern parts PAP1-1 may extend further in the first direction DR1 than in the second direction DR2. The first opening portions OP1a in the (1-1)-th pattern parts PAP1-1 may be arranged (e.g., spaced apart from one another) in (or along) the first direction DR1 and the second direction DR2. The first opening portions OP1a adjacent to each other in the second direction DR2 may be misaligned with each other. For instance, the first opening portions OP1a adjacent to each other in the second direction DR2 may be arranged in a staggered pattern, e.g., may be offset from one another in (or along) the first direction DR1.

The first opening portions OP1a in (1-2)-th pattern parts PAP1-2 may extend further in the second direction DR2 than in the first direction DR1. The first opening portions OP1a in the (1-2)-th pattern parts PAP1-2 may be arranged (e.g., spaced apart from one another) in (or along) the first direction DR1 and the second direction DR2. The first opening portions OP1a adjacent to each other in the first direction DR1 may be misaligned with each other. For instance, the first opening portions OP1a adjacent to each other in the first direction DR1 may be arranged in a staggered pattern, e.g., may be offset from one another in (or along) the second direction DR2.

Referring to FIGS. 10A and 10C, second patterns PT2 may be second opening portions OP2a in a second pattern part PAP2. The second opening portions OP2a may each have a shape corresponding to a corner of the display part TA in a plan view. Each of the second opening portions OP2a may include a first part extending in (or along) the first direction DR1 and a second part extending in (or along) the second direction DR2. An extending direction of the second opening portions OP2a may be changed at least one time.

As an example, the second opening portions OP2a may each have a shape corresponding to a portion of a rhombus extending in the first direction DR1 and a portion of a rhombus extending in the second direction DR2, which overlap or conjoin with each other to form an “L”-like or rotated “L”-like shape in a plan view.

Referring to FIGS. 10A to 10C, at least because the first opening portions OP1a are included, in a case that the external impact F (see FIG. 9A) is applied to the first pattern parts PAP1, the first pattern parts PAP1 may be bent (or deformed) toward the first opening portions OP1. At least because the second opening portions OP2a are included, in a case that the external impact F (see FIG. 9A) is applied to the second pattern parts PAP2, the second pattern parts PAP2 may be bent (or deformed) toward the second opening portions OP2a.

According to some embodiments, the first pattern parts PAP1 and the second pattern parts PAP2 may absorb a force of the external impact F (see FIG. 9A). Absorption of the force of the external impact F applied to the window WMa may prevent (or mitigate the likelihood of) the display part TA being damaged, and thereby, may improve the quality and/or reliability of the electronic apparatus EA (see FIG. 1) that displays the image IM for a user. The presence of the first opening portions OP1a and the second opening portions OP2a may also prevent (or at least reduce the likelihood of) propagation of the crack CK (see FIG. 9B) and/or the combining of one or more cracks CK (see FIG. 9B).

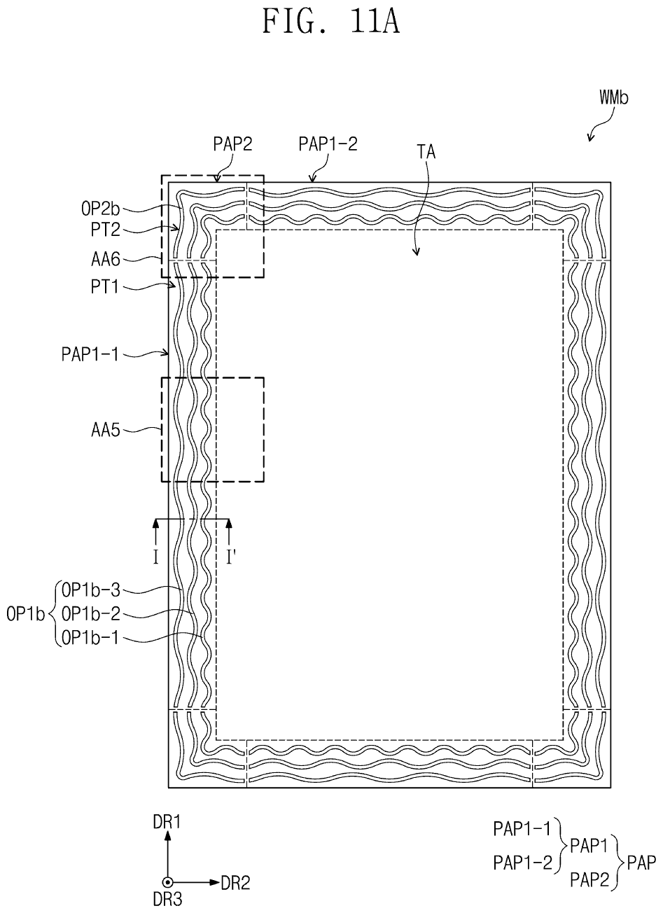

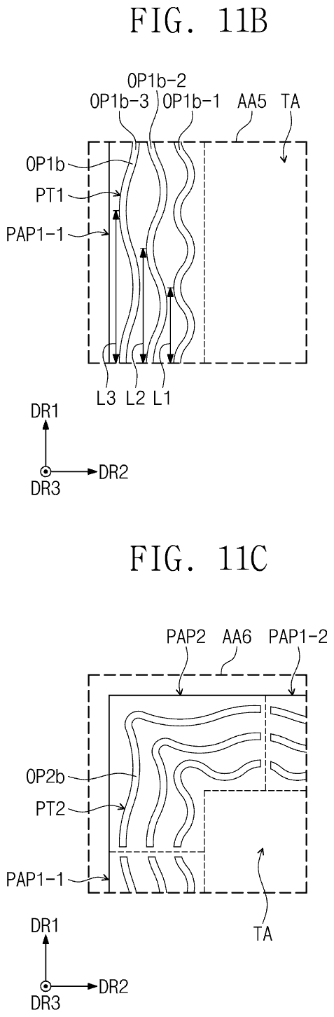

FIGS. 11A to 11C are schematic views for describing a first pattern and a second pattern according to an embodiment.

As an example, FIG. 11A is a schematic plan view of a window WMb, FIG. 11B is an enlarged schematic plan view of a fifth area AA5 illustrated in FIG. 11A, and FIG. 11C is an enlarged schematic plan view of a sixth area AA6 illustrated in FIG. 11A according to an embodiment.

As an example, a (1-1)-th pattern part PAP1-1 of the window WMb will be described with reference to FIG. 11B, but a (1-2)-th pattern part PAP1-2 may also have substantially a same structure as the (1-1)-th pattern part PAP1-1.

A display part TA of the window WMb illustrated in FIGS. 11A to 11C is equivalent to the display part TA described in conjunction with FIG. 6, and thus, will not be described or will be briefly described.

For convenience of explanation, the window WMb in FIGS. 11A to 11C will be described mainly in terms of differences with the window WM described in association with FIG. 6.

Referring to FIGS. 11A and 11B, first patterns PT1 may be multiple first opening portions OP1b in a first pattern part PAP1. The first opening portions OP1b may have a shape corresponding to a wavy (or meandering) pattern having multiple peaks and multiple troughs in a plan view. The troughs may be concave portions of the first opening portions OP1b that are recessed toward the display part TA in a plan view. The peaks may be convex portions of the first opening portions OP1b that protrude toward an edge of the window WMb in a plan view.

The first opening portions OP1b in (1-1)-th pattern parts PAP1-1 may extend in (or along) the first direction DR1 in a plan view. The respective troughs and peaks of the first opening portions OP1b in the (1-1)-th pattern parts PAP1-1 may be alternately arranged in (or along) the first direction DR1. The first opening portions OP1b in the (1-1)-th pattern parts PAP1-1 may be arranged in (or along) the second direction DR2. The first opening portions OP1b may include (1-1)-th opening portions OP1b-1, (1-2)-th opening portions OP1b-2, and (1-3)-th opening portions OP1b-3 that may be arranged in order of increasing distance from the display part TA with the (1-1)-th opening portions OP1b-1 being closest to the display part TA and the (1-3)-th opening portions being furthest from the display part TA. As an example, three first opening portions OP1b are defined in the (1-1)-th pattern parts PAP1-1, but a number of the first opening portions OP1b is not limited to three. For instance, the (1-1)-th pattern parts PAP1-1 may include less than three first opening portions OP1b or may include four or more first opening portions OP1b.

The first opening portions OP1b in (1-2)-th pattern parts PAP1-2 may extend in (or along) the second direction DR2. The respective troughs and peaks of the first opening portions OP1b in the (1-2)-th pattern parts PAP1-2 may be alternately arranged in (or along) the second direction DR2. The first opening portions OP1b in the (1-2)-th pattern parts PAP1-2 may be arranged in (or along) the first direction DR1. As an example, three first opening portions OP1b are defined in the (1-2)-th pattern parts PAP1-2, but a number of the first opening portions OP1b is not limited to three. For instance, the (1-2)-th pattern parts PAP1-2 may include less than three first opening portions OP1b or may include four or more first opening portions OP1b.

Referring to FIG. 11B, in a plan view, a length of a wavelength of the first opening portions OP1b adjacent to the display part TA and a length of a wavelength of the first opening portions OP1b spaced apart from the display part TA may be different from each other. The length of the wavelength of the first opening portions OP1b may be defined as a length between the peaks adjacent to each other in the first direction DR1, or a length between the troughs adjacent to each other in the first direction DR1.

The length of the wavelength of the first opening portions OP1b adjacent to the display part TA may be less than the length of the wavelength of the first opening portions OP1b spaced apart from the display part TA. As an example, a length of a wavelength of a (1-1)-th opening portion OP1b-1 may be a first length L1. A length of a wavelength of a (1-2)-th opening portion OP1b-2 may be a second length L2. A length of a wavelength of a (1-3)-th opening portion OP1b-3 may be a third length L3. The second length L2 may be greater than the first length L1, and less than the third length L3.

An embodiment, in which the lengths of the wavelengths of the first opening portions OP1b increase in order with increasing distance from the display part TA toward edges of the window WMb, is described as an example. However, embodiments are not limited to this example. For instance, the lengths of the wavelengths of the first opening portions OP1b may decrease in order of increasing distance from the display part TA toward the edges the window WMb or may have any other suitable relationship.

Although the first opening portions OP1b in the (1-1)-th pattern part PAP1-1 are described with reference to FIG. 11B, the first opening portions OP1b defined in the (1-2)-th pattern part PAP1-2 (see FIG. 11A) may also have a substantially equivalent structure as the first opening portions OP1b in the (1-1)-th pattern part PAP1-1, except an extending direction may be different.

Referring to FIGS. 11A and 11C, second patterns PT2 may be second opening portions OP2b in second pattern parts PAP2. The second opening portions OP2b may each have a shape corresponding to a corner of the display part TA in a plan view. Each of the second opening portions OP2b may include a first part extending in (or along) the first direction DR1 and a second part extending in (or along) the second direction DR2. An extending direction of the second opening portions OP2b may be changed at least one time.

As an example, portions of the second opening portions OP2b, which correspond to a corner of the display part TA, may each have a shape protruding toward a corresponding corner of an associated second pattern part PAP2 among the second pattern parts PAP2 in a plan view. The portions of the second opening portions OP2b, which protrude toward the corner of the second pattern part PAP2, may each have a bowed shape toward a corner of the second pattern part PAP2 that is more adjacent to the display part TA than to edges of the window WMb. For instance, portions of the second opening portions OP2b may have a convex curvature bowing toward the display part TA.

Referring to FIGS. 11A to 11C, at least because the first opening portions OP1b are included, in a case that the external impact F (see FIG. 9A) is applied to the first pattern parts PAP1, the first pattern parts PAP1 may be bent (or deformed) toward the first opening portions OP1b. At least because the second opening portions OP2b are included, in a case that the external impact F (see FIG. 9A) is applied to the second pattern parts PAP2, the second pattern parts PAP2 may be bent (or deformed) toward the second opening portions OP2b.

According to some embodiments, the first pattern parts PAP1 and the second pattern parts PAP2 may absorb a force of the external impact F (see FIG. 9A). Absorption of the force of the external impact F applied to the window WMb may prevent (or mitigate the likelihood of) the display part TA being damaged, and thereby, may improve the quality and/or reliability of the electronic apparatus EA (see FIG. 1) that displays the image IM for a user. The presence of the first opening portions OP1b and the second opening portions OP2b may also prevent (or at least reduce the likelihood of) propagation of the crack CK (see FIG. 9B) and/or the combining of one or more cracks CK (see FIG. 9B).

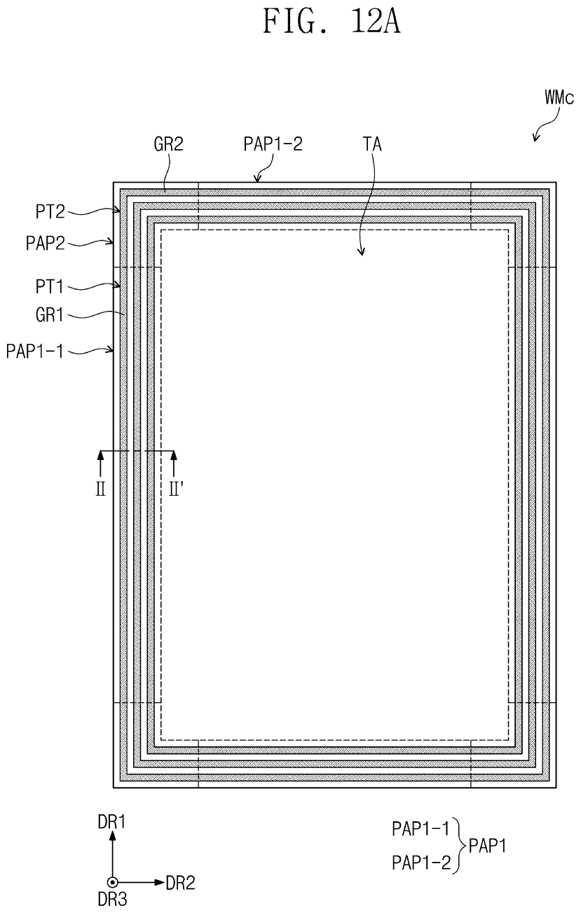

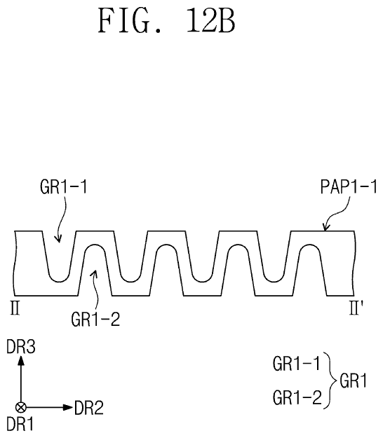

FIGS. 12A and 12B are schematic views for describing a window according to an embodiment.

As an example, FIG. 12A is a schematic plan view of window WMc, and FIG. 12B is a schematic cross-sectional view of window WMc taken along sectional line II-II′ illustrated in FIG. 12A according to an embodiment.

As an example, in FIG. 12A, first and second grooves GR1 and GR2 illustrated with a hatched pattern to distinguish the first and second grooves GR1 and GR2 from surfaces (e.g., top surfaces) of the first and second pattern parts PAP1 and PAP2.

As an example, the first grooves GR1 in a (1-1)-th pattern part PAP1-1 are described with reference to FIG. 12B, but the first grooves GR1 in a (1-2)-th pattern part PAP1-2 (see FIG. 12A) may also have a substantially equivalent structure as the first grooves GR1 in the (1-1)-th pattern part PAP1-1, except an extending direction may be different.

A display part TA of the window WMc illustrated in FIGS. 12A and 12B is equivalent to the display part TA described in conjunction with FIG. 6, and thus, will not be described or will be briefly described.

Referring to FIGS. 12A and 12B, first patterns PT1 may be multiple first grooves GR1 in the first pattern parts PAP1. The first grooves GR1 in (1-1)-th pattern parts PAP1-1 may extend in (or along) the first direction DR1 in a plan view. The first grooves GR1 in the (1-1)-th pattern parts PAP1-1 may be arranged in (or along) the second direction DR2 in a plan view. Hereinafter, the first grooves GR1 in the (1-1)-th pattern parts PAP1-1 will be described.

The first grooves GR1 may include (1-1)-th grooves GR1-1 and (1-2)-th grooves GR1-2. The (1-1)-th grooves GR1-1 may be defined in first (e.g., top) surfaces of the (1-1)-th pattern parts PAP1-1. In a plan view, the (1-1)-th grooves GR1-1 may extend in (or along) the first direction DR1 and may be spaced apart from each other in (or along) the second direction DR2. Each of the (1-1)-th grooves GR1-1 may extend from the first (e.g., top) surface toward a second (e.g., bottom) surface of each of the (1-1)-th pattern parts PAP1-1 in the third direction DR3. The (1-1)-th grooves GR1-1 may each have a concave downward shape relative to the first (e.g., top) surfaces of the (1-1)-th pattern parts PAP1-1. The (1-1)-th grooves GR1-1 may each extend to be longer than half (½) a thickness of the (1-1)-th pattern part PAP1-1. For instance, the (1-1)-th grooves GR1-1 may each have a depth in the third direction DR3 greater than half (½) a thickness of the (1-1)-th pattern part PAP1-1 in the third direction DR3.

The (1-2)-th grooves GR1-2 may extend from the second (e.g., bottom) surface toward the first (e.g., top) surface of the (1-1)-th pattern part PAP1-1 in the third direction DR3. The (1-2)-th grooves GR1-2 may each have a convex upward shape relative to the first (e.g., top) surface of the (1-1)-th pattern part PAP1-1. The (1-2)-th grooves GR1-2 may each extend to be longer than half (½) a thickness of the (1-1)-th pattern part PAP1-1. For instance, the (1-2)-th grooves GR1-2 may each have a depth in the third direction DR3 greater than half (½) a thickness of the (1-1)-th pattern part PAP1-1 in the third direction DR3.

Referring to FIG. 12A, the first grooves GR1 in the (1-2)-th pattern parts PAP1-2 may extend in (or along) the second direction DR2 and may be arranged in (or along) the first direction DR1. Although not illustrated, the first grooves GR1 in the (1-2)-th pattern part PAP1-2 may also have substantially a same structure as the first grooves GR1 in the (1-1)-th pattern parts PAP1-1, except an extending direction may be different. For instance, the first grooves GR1 may be defined in the first and second (e.g., top and bottom) surfaces of the (1-2)-th pattern parts PAP1-2.

Second patterns PT2 may be the second grooves GR2 in the second pattern parts PAP2. The second grooves GR2 may include a first part extending in (or along) the first direction DR1 and a second part extending in (or along) the second direction DR2 in a plan view. An extending direction of the second grooves GR2 may be changed at least one time. The second grooves GR2 may each have a gnomon shape (e.g., a rectangular gnomon shape, such as an “L” or a rotated “L” shape) in a plan view. The shape of the second grooves GR2 in a plan view may be symmetrical about an axis of symmetry extending between vertices of the window WMc and the display part TA in a plane parallel (or substantially parallel) to a DR1-DR2 plane.

Although not illustrated, the second grooves GR2 may be defined in not only first (e.g., top) surfaces of the second pattern parts PAP2, but may also be formed in second (e.g., bottom) surfaces of the second pattern parts PAP2 similar to the configuration of the first grooves GR1 defined in the first and second (e.g., top and bottom) surfaces of the first pattern parts PAP1. For instance, the second grooves GR2 may have substantially a same structure as the first grooves GR1, except an extending direction may be different.

Referring to FIGS. 12A and 12B, in a case that the external impact F (see FIG. 9A) is applied to the first pattern parts PAP1, the first pattern parts PAP1 may be bent (or deformed) toward the first grooves GR1. In a case that the external impact F (see FIG. 9A) is applied to the second pattern parts PAP2, the second pattern parts PAP2 may be bent (or deformed) toward the second grooves GR2. At least because the first pattern parts PAP1 and/or the second pattern parts PAP2 may be bent, a force of the external impact F (see FIG. 9A) may be absorbed. Absorption of the force of the external impact F applied to the window WMc may prevent (or mitigate the likelihood of) the display part TA being damaged, and thereby, may improve the quality and/or reliability of the electronic apparatus EA (see FIG. 1) that displays the image IM for a user. In a case in which the crack CK (see FIG. 9B) is generated in the first pattern parts PAP1 and/or the second pattern parts PAP2, the presence of the first grooves GR1 and/or the second grooves GR2 may also prevent (or at least reduce the likelihood of) propagation of the crack CK (see FIG. 9B) to the display part TA and/or the combining of one or more cracks CK (see FIG. 9B).

FIGS. 13A and 13B are schematic views for describing a bezel part illustrated in FIG. 2 according to an embodiment.

As an example, FIG. 13A is a schematic plan view of window WMd, and FIG. 13B is a schematic cross-sectional view taken along sectional line III-III′ illustrated in FIG. 13A of window WMd.

As an example, first pattern parts PAP1, second pattern parts PAP2, and a display part TA in FIGS. 13A and 13B are equivalent to the first pattern parts PAP1, the second pattern parts PAP2, and the display part TA described in association with FIG. 6, respectively, and thus, will not be described or will be briefly described.

Referring to FIG. 13A, a window WMd may further include a bezel part BZA. The bezel part BZA may be (or include) a resin RS. The resin RS may include a light-blocking material, such as a black material configured to block light. The first pattern parts PAP1 and the second pattern parts PAP2 may be prevented from being visible from the outside. The resin RS may have an elastic modulus in a range of about 1 MPa to about 5000 MPa at room temperature, which may be in a range of about 20° C. to about 22° C.

The bezel part BZA may cover the first pattern parts PAP1 and the second pattern parts PAP2 in a plan view. The resin RS may be disposed on first (e.g., top) surfaces of the first pattern parts PAP1 and the second pattern parts PAP2. The bezel part BZA may surround the display part TA in a plan view.

Referring to FIGS. 13A and 13B, the resin RS may be filled in first opening portions OP1. In a case that the external impact F (see FIG. 9A) is applied to the first pattern parts PAP1, the resin RS may serve as a buffer that absorbs a force of the external impact F (see FIG. 9A). Absorption of the force of the external impact F applied to the window WMd may prevent (or mitigate the likelihood of) the window WMd and/or the display part TA being damaged.

As an example, the resin RS may be disposed on second (e.g., bottom) surfaces of the first pattern parts PAP1. The resin RS may cover the second (e.g., bottom) surfaces of the first pattern parts PAP1. However, embodiments are not limited to this example structure. For instance, the resin RS disposed on the second (e.g., bottom) surfaces of the first pattern parts PAP1 may be omitted.

Although not illustrated in a schematic cross-sectional view, the resin RS may be disposed in second opening portions OP2 in the second pattern parts PAP2 similar to the resin RS being disposed in the first opening portions OP1. The resin RS may be disposed on first and/or second (e.g., top and/or bottom) surfaces of the second pattern parts PAP2 similar to the resin RS being disposed on the first and/or second (e.g., top and/or bottom) surfaces of the first pattern parts PAP1. The resin RS may absorb a force of the external impact F (see FIG. 9A) applied to the second pattern parts PAP2 to prevent (or at least mitigate the potential of) the window WMd and/or the display part TA being damaged.

In some implementations, the resin RS may be disposed in the first opening portions OP1 and the second opening portions OP2, and not disposed on the first nor second (e.g., top nor bottom) surfaces of the first pattern parts PAP1 and the second pattern parts PAP2. It is also contemplated that an impact absorbing material (e.g., one or more polymers, such as at least one of polyurethane, sorbothane™, polychloroprene, a liquid crystal elastomer, silicone, rubber, and/or the like) may be filled in the first opening portions OP1 and the second opening portions OP2, and the resin RS may be disposed on at least one of the first and second (e.g., top and bottom) surfaces of the bezel part BZA of the window WMd. At least one material of the resin RS may be different from at least one material of the impact absorbing material. In some embodiments, the impact absorbing material may be or include granular matter that is contained in the first opening patterns OP1 and the second opening patterns OP2 by, for instance, the resin RS disposed on the first and second (e.g., top and bottom) surfaces of the bezel BZA.

FIG. 14 is a schematic plan view of a window according to an embodiment.

As an example, first pattern parts PAP1, second pattern parts PAP2, and a display part TA in FIG. 14 are equivalent to the first pattern parts PAP1, the second pattern parts PAP2, and the display part TA described in conjunction with FIGS. 6 and 13A, respectively, and thus, will not be described or will be briefly described.

Referring to FIG. 14, a bezel part BZAa of window WMe may be a resin RSa. The resin RSa may be optically transparent. As an example, the resin RSa may include at least one of urethane, polycarbonate (PC), polyethylene (PE), acryl, polyimide (PI), polyamide (PA), and silicon. As an example, the resin RSa may have an elastic modulus in a range of about 1 MPa to about 5000 MPa at room temperature, which may be in a range of about 20° C. to about 22° C.

The resin RSa may be disposed on first (e.g., top) surfaces of the first pattern parts PAP1, first (e.g., top) surfaces of the second pattern parts PAP2, and a first (e.g., top) surface of the display part TA. Accordingly, the resin RSa may protect (or mitigate the likelihood of) the first (e.g., top) surfaces of the first pattern parts PAP1, the first (e.g., top) surfaces of the second pattern parts PAP2, and the first (e.g., top) surface of the display part TA from being scratched.

Although not illustrated in a schematic cross-sectional view, the resin RSa may be filled in first opening portions OP1 and second opening portions OP2 of window WMe. At least because the resin RSa is disposed in the first opening portions OP1 and the second opening portions OP2, the resin RSa may absorb a force of the external impact F (see FIG. 9A). Absorption of the force of the external impact F applied to the window WMe may prevent (or mitigate the likelihood of) the window WMe and/or the display part TA being damaged.

According to various embodiments, opening portions and/or grooves may be defined in one or more pattern parts of a window that surround a display part of the window. In a case in which an external impact is applied to the window, the one or more pattern parts may serve as a buffer that reduces a force of the external impact. Absorption of the force of the external impact by the one or more pattern parts may prevent (or mitigate the likelihood of) the window and/or the display part being damaged.

According to various embodiments, the inclusion of one or more opening portions and/or grooves in the one or more pattern parts, even in a case that a crack is generated (or formed) in the one or more pattern parts due to the external impact, the crack may be prevented (or at least hindered) from propagating to the display part and/or combining with at least one other crack. Preventing or reducing crack propagation may prevent or at least reduced the likelihood that the display part becomes damaged, and, thereby, may improve the quality and/or reliability of an electronic apparatus including the window.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A window comprising:
a display part having first sides extending in a first direction and second sides extending in a second direction transverse to the first direction;
a pattern part surrounding the display part in a view in a third direction, the third direction being perpendicular to the first direction and the second direction,
wherein the pattern part comprises:
a first pattern part extending along a side among the first sides and the second sides of the display part, the first pattern part comprising a first pattern in the window; and
a second pattern part adjacent to a transition region of the display part, the transition region connecting a first side among the first sides to a second side among the second sides, the second pattern part comprising a second pattern in the window, and
wherein, in the view, a shape of the first pattern is different from a shape of the second pattern.

2. The window of claim 1, wherein, in the view, an extending direction of the first pattern is along the side of the display part, and an extending direction of the second pattern changes at least one time.

3. The window of claim 2, wherein
the first pattern comprises a first opening portion extending through the first pattern part in the third direction, and
the second pattern comprises a second opening portion extending through the second pattern part in the third direction.

4. The window of claim 3, wherein
the first sides are long sides of the display part,
the second sides are short sides of the display part,
the side is one of the first sides,
the first pattern comprises a plurality of the first opening portion, at least two of the first opening portions being spaced apart from one another in the first direction and at least two of the first opening portions being spaced apart from one another in the second direction, and
the at least two first opening portions spaced apart from one another in the second direction are offset from one another in the first direction.

5. The window of claim 3, wherein
the first sides are long sides of the display part,
the second sides are short sides of the display part,
the side is one of the second sides,
the first pattern comprises a plurality of the first opening portion, at least two of the first opening portions being spaced apart from one another in the first direction and at least two of the first opening portions are spaced apart from one another in the second direction, and
the at least two first opening portions spaced apart from one another in the first direction are offset from one another in the second direction.

6. The window of claim 3, wherein
the first sides are along sides of the display part,
the second sides are short sides of the display part,
the side is one of the long sides,
the first pattern comprises a plurality of the first opening portion, the first opening portions being spaced apart from one another in the second direction,
each of the first opening portions has a corresponding wavy pattern shape in the view, and
a distance between waves of a first opening portion among the first opening portions that is closer to the display part than another first opening portion among the first opening portions is different from a distance between waves of the another first opening portion.

7. The window of claim 3, wherein
the first sides are along sides of the display part,
the second sides are short sides of the display part,
the side is one of the short sides,
the first pattern comprises a plurality of the first opening portion, the first opening portions being spaced apart from one another in the first direction,
each of the first opening portions has a corresponding wavy pattern shape in the view, and
a distance between waves of a first opening portion among the first opening portions that is closer to the display part than another first opening portion among the first opening portions is different from a distance between waves of the another first opening portion.

8. The window of claim 3, wherein first parts of inner side surfaces of the first opening portion extend in the third direction and face one another in a direction perpendicular to the third direction.

9. The window of claim 8, wherein
second parts of the inner side surfaces of the first opening portion are oblique to the first parts and connect the first parts to a first surface of the pattern part, the first opening portion having a first end in the first surface; and
third parts of the inner surfaces of the first opening portion are oblique to the first parts and connect the first parts to a second surface of the pattern part opposing the first surface of the pattern part in the third direction, the first opening portion having a second end in the second surface.

10. The window of claim 3, wherein inner side surfaces of the first opening portion bow convexly toward a central axis of the first opening portion.

11. The window of claim 3, wherein
a transverse plane divides inner side surfaces of the first opening portion into first surface parts adjacent to a first side of the transverse plane and second surface parts adjacent to a second side of the transverse plane, and
a shortest distance between the first surface parts continuously increases in size from the transverse plane toward a first surface of the pattern part along the third direction, the first opening portion terminating at the first surface.

12. The window of claim 3, wherein
the first opening portion is at least partially filled with a resin, and
the second opening portion is at least partially filled with the resin.

13. The window of claim 12, wherein
the pattern part comprises a first surface at which first ends of the first opening portion and the second opening portion terminate and a second surface at which second ends of the first opening portion and the second opening portion terminate,
at least one of the first surface and the second surface is coated with the resin, and
the resin is a light-blocking resin.

14. The window of claim 12, wherein
the pattern part comprises a first surface at which first ends of the first opening portion and the second opening portion terminate and a second surface at which second ends of the first opening portion and the second opening portion terminate,
at least one of the first surface and the second surface is coated with the resin, and
the resin is optically transparent.

15. The window of claim 12, wherein, in a range of about 20° C. to about 22° C., the resin has an elastic modulus in a range of about 1 MPa to about 5000 MPa.

16. The window of claim 2, wherein
the first pattern comprises a first groove in the first pattern part, and
the second pattern comprises a second groove in the second pattern part.

17. The window of claim 16, wherein
the first groove comprises:
a (1-1)-th groove extending from a first surface of the first pattern part toward a second surface of the first pattern part, the second surface opposing the first surface; and
a (1-2)-th groove extending from the second surface of the first pattern part toward the first surface of the first pattern part, and
each of the (1-1)-th groove and the (1-2)-th groove has a depth that is greater than half a thickness of the first pattern part.

18. The window of claim 1, wherein
the first sides are long sides of the display part,
the second sides are short sides of the display part, and
the side is one of the long sides and a width of the first pattern part in the second direction is in a range of about 50 μm to about 5000 μm, or
the side is one of the short sides and a width of the first pattern part in the first direction is in a range of about 50 μm to about 5000 μm.

19. A display device comprising:
a display panel; and
a window disposed on the display panel, the window comprising:
a display part having first sides extending in a first direction and second sides extending in a second direction transverse to the first direction; and
a pattern part surrounding the display part in a view in a third direction perpendicular to the first direction and the second direction,
wherein the pattern part comprises:
a first pattern part extending along a side among the first sides and the second sides of the display part, the first pattern part comprising a plurality of first opening portions in the window; and
a second pattern part adjacent to a transition region of the display part, the transition region connecting a first side among the first sides to a second side among the second sides, the second pattern part comprising a plurality of second opening portions in the window,
wherein, in the view, shapes of each of the plurality of first opening portions are different from shapes of each of the plurality of second opening portions.

20. The display device of claim 19, wherein at least some of the first opening portions and the second opening portions are at least partially filled with resin.

21. A window comprising:
a display part disposed in a central portion of the window;
a first pattern part extending in a first direction and disposed between a first portion of a periphery of the window and the central portion in a view in a third direction perpendicular to the first direction;
a second pattern part extending in a second direction transverse to the first direction and perpendicular to the third direction, the second pattern part being disposed between a second portion of the periphery and the central portion in the view; and
a third pattern part disposed between a third portion of the periphery and the central portion in the view, the third portion of the periphery connecting the first portion of the periphery to the second portion of the periphery, wherein
a first section of the third pattern part extends in the first direction,
a second section of the third pattern part extends in the second direction,
the first pattern part comprises a first void pattern in the window, and
the third pattern part comprises a second void pattern in the window, the second void pattern being different from the first void pattern.
